(19) United States
(12) Patent Application Publication
(10) Pub. No.: US 2023/0235969 A1
(43) Pub. Date: Jul. 27, 2023

(54) TEMPERATURE CONTROL APPARATUS WITH HEAT EXCHANGING UNIT DIVIDED INTO EVAPORATOR AND CONDENSER SECTIONS

(71) Applicant: DELTA ELECTRONICS, INC., Taoyuan City (TW)

(72) Inventors: Hsueh-Chi PAN, Taoyuan City (TW); Tse-Hsin WANG, Taoyuan City (TW); Chia-Wei CHEN, Taoyuan City (TW); Ying-Chi CHEN, Taoyuan City (TW)

(21) Appl. No.: 18/126,818

(22) Filed: Mar. 27, 2023

Related U.S. Application Data
(62) Division of application No. 16/721,461, filed on Dec. 19, 2019.

(30) Foreign Application Priority Data
Dec. 27, 2018 (CN) 201811608719.8

(51) Int. Cl. F28D 15/04

(52) U.S. Cl. CPC F28D 15/043

(57) ABSTRACT

A temperature control apparatus is disposed in a first environment and a second environment. The temperature control apparatus includes a heat exchanging unit and a working fluid. The heat exchanging unit is independently disposed and divided into a first heat exchanging portion and a second heat exchanging portion. The heat exchanging unit includes a pipe and a plurality of heat-dissipating fins for cooling the pipe. Two ends of the pipe are connected to from a closed pipe. The pipe runs in the first and the second heat exchanging portions alternately. The heat-dissipating fins are not continuously disposed in the first heat exchanging portion and the second heat exchanging portion. The first heat exchanging portion is correspondingly disposed at the first environment. The second heat exchanging portion is correspondingly disposed at the second environment. The working fluid flows in the pipe.

### CROSS REFERENCE TO RELATED APPLICATIONS

This Non-provisional application is a Divisional Application (DA) of an earlier filed, pending application, having application Ser. No. 16/721,461 and filed on Dec. 19, 2019, which claims priority under 35 U.S.C. § 119(a) on Patent Application No(s). 201811608719.8 filed in People's Republic of China on Dec. 27, 2018, the entire contents of which are hereby incorporated by reference.

### BACKGROUND OF THE DISCLOSURE

### Field of Disclosure

The present disclosure relates to a temperature control apparatus and a heat exchanging unit, and, in particular, to a heat exchanging unit having the functions of condenser and evaporator simultaneously.

### Related Art

A conventional communication cabinet is provided to accommodate the electronic communication device, the power converter, or the backup battery. The cabinet body is mostly made of metal material, and the cabinet usually has the waterproof and dustproof functions for protecting the electronic elements therein. A closed space is provided inside the cabinet, so that a heat-dissipation apparatus is needed to be disposed on the cabinet for cooling the temperature inside the cabinet.

The conventional heat-dissipation apparatus, such as a hybrid air conditioner, is to integrate a heat-pipe heat exchanger and an air-conditioner heat exchanger to achieve the two functions in one machine. However, it is required to include two or more heat-pipe heat exchangers, so the internal pipeline configuration is complicated and requires many components such as pipeline path switching valves, expansion valves and the likes. Moreover, the complicated pipelines must be connected through welding, which not only increases the cost and manufacturing time, but also easily causes assembly errors.

Therefore, it is desired to provide a heat exchanging unit having the functions of condenser and evaporator simultaneously, so that the temperature control apparatus can be manufactured with less amount of components, and the welding processes can be reduced so as to decrease the assembling errors.

### SUMMARY OF THE DISCLOSURE

An objective of this disclosure is to provide a heat exchanging unit having the functions of condenser and evaporator simultaneously and a temperature control apparatus with the heat exchanging unit. Compared with the conventional temperature control apparatus, the temperature control apparatus of this disclosure can be manufactured with less amount of components, and the welding processes thereof can be reduced so as to decrease the assembling errors. Moreover, the size of the temperature control apparatus can be decreased, the manufacturing cost thereof can be lowered, the entire function thereof can be enhanced, and the heat-dissipation surface can be increased.

A temperature control apparatus is disposed in a first environment and a second environment. The temperature control apparatus comprises a heat exchanging unit, a compressor, a circulation loop, and a working fluid. The heat exchanging unit is divided into a first heat exchanging portion and a second heat exchanging portion. The heat exchanging unit comprises a plurality of heat-dissipating fins and at least one pipe. The at least one pipe runs in the first heat exchanging portion and then runs in the second heat exchanging portion. The heat-dissipating fins are configured to cool the at least one pipe. The first heat exchanging portion is correspondingly disposed at the first environment, and the second heat exchanging portion is correspondingly disposed at the second environment. The circulation loop is communicated to the heat exchanging unit and the compressor, and the working fluid flows in the circulation loop. The compressor compresses the working fluid for performing the temperature regulation function.

In one embodiment, the first heat exchanging portion is a condensing region, and the second heat exchanging portion is an evaporation region.

In one embodiment, the at least one pipe comprises an inlet and an outlet, the inlet and the outlet are disposed in the first heat exchanging portion and the second heat exchanging portion, respectively, and the inlet and the outlet of the at least one pipe of the heat exchanging unit are connected with the circulation loop.

In one embodiment, the at least one pipe comprises a plurality of pipes, at least one of the pipes has a larger pipe diameter around the inlet and the outlet and has a smaller pipe diameter away from the inlet and the outlet.

In one embodiment, the at least one pipe comprises a plurality of pipes, and the working fluid is not allowed to pass through at least one of the pipes.

In one embodiment, the temperature control apparatus further comprises a first fan and a second fan. The first fan is disposed in the first environment corresponding to the first heat exchanging portion, and the second fan is disposed in the second environment corresponding to the second heat exchanging portion.

In one embodiment, the heat-dissipating fins are not continuously disposed in the first and second heat exchanging portions.

In one embodiment, the at least one pipe is a flat pipe, a circular pipe, an oval pipe, a rectangular pipe, or a corrugated pipe.

In one embodiment, the at least one pipe comprises a capillary zone, and a total cross-sectional area of the at least one pipe outside the capillary zone is greater than a total cross-sectional area of the at least one pipe in the capillary zone.

A heat exchanging unit is disposed in a first environment and a second environment. The heat exchanging unit comprises a plurality of heat-dissipating fins, at least one pipe, and at least one working fluid. The heat exchanging unit is divided into a first heat exchanging portion and a second heat exchanging portion. The at least one pipe runs in the first and second heat exchanging portions alternately. The heat-dissipating fins are configured to cool the at least one pipe. The first and second heat exchanging portions are correspondingly disposed at the first and second environments, respectively. The at least one working fluid is disposed in the at least one pipe.

In one embodiment, the at least one pipe is a closed pipe.

In one embodiment, the heat-dissipating fins are not continuously disposed in the first and second heat exchanging portions.

In one embodiment, the heat exchanging unit is not connected with any compressor.

As mentioned above, the temperature control apparatus of this disclosure can be manufactured with less amount of components, and the welding processes thereof can be reduced. Moreover, the size of the temperature control apparatus can be decreased, the manufacturing cost thereof can be lowered, the entire function thereof can be enhanced, and the heat-dissipation surface can be increased.

### BRIEF DESCRIPTION OF THE DRAWINGS

The present disclosure will become more fully understood from the subsequent detailed description and accompanying drawings, which are given by way of illustration only, and thus are not limitative of the present disclosure, and wherein:

FIG. 1 is a schematic diagram showing a temperature control apparatus according to an embodiment of this disclosure;

FIG. 2A is a schematic diagram showing a heat exchanging unit of the temperature control apparatus according to a first embodiment of this disclosure;

FIG. 2B is a schematic diagram showing a heat exchanging unit of the temperature control apparatus according to a second embodiment of this disclosure;

FIG. 3A is a schematic diagram showing a heat exchanging unit according to a third embodiment of this disclosure; and

FIG. 3B is a schematic diagram showing a heat exchanging unit according to a fourth embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

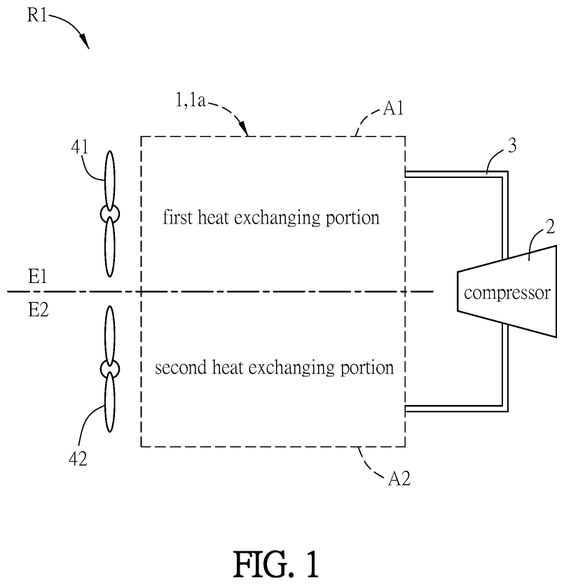

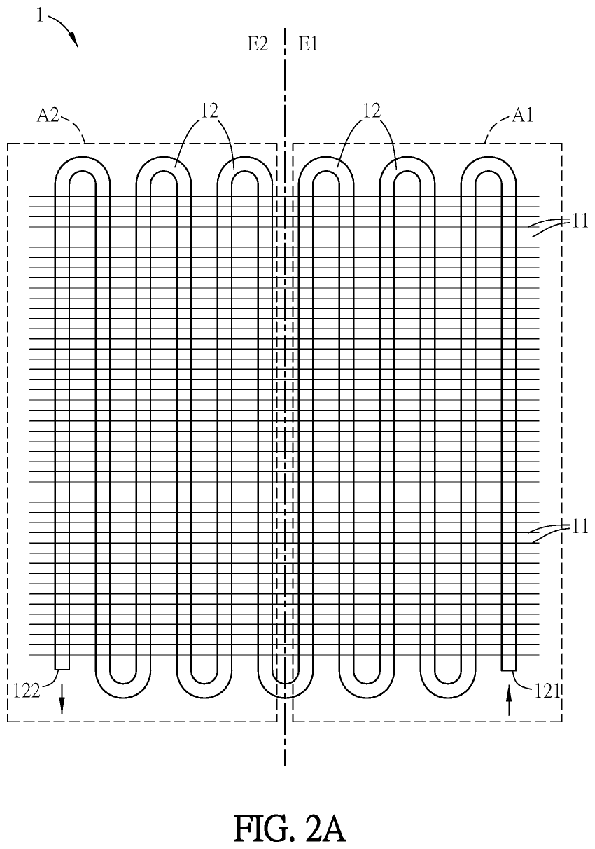

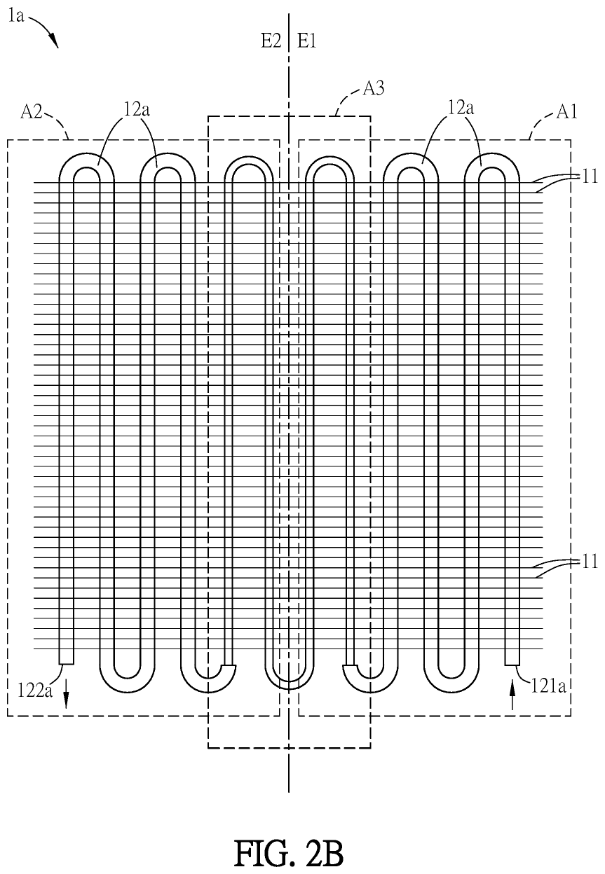

FIG. 1 is a schematic diagram showing a temperature control apparatus R1 according to an embodiment of this disclosure. Referring to FIGS. 1 and 2A, the temperature control apparatus R1 is disposed in a first environment E1 and a second environment E2. The temperature control apparatus R1 comprises a heat exchanging unit 1/1a, a compressor 2, a circulation loop 3, and a working fluid. The heat exchanging unit 1/1a is divided into a first heat exchanging portion A1 and a second heat exchanging portion A2.

FIG. 2A is a schematic diagram showing a heat exchanging unit 1 of the temperature control apparatus R1 of FIG. 1 according to a first embodiment of this disclosure. Referring to FIG. 2A in view of FIG. 1, the heat exchanging unit 1 comprises a plurality of heat-dissipating fins 11 and at least one pipe 12. The pipe 12 runs in the first heat exchanging portion A1 and then runs in the second heat exchanging portion A2. The heat-dissipating fins 11 are configured to cool the pipe 12. The first and second heat exchanging portions A1, A2 are correspondingly disposed at the first and second environments E1, E2, respectively. For example, all components of the temperature control apparatus R1 can be accommodated in one case (not shown). The temperature control apparatus R1 comprises one heat exchanging unit 1, and is divided into the first and second heat exchanging portions A1, A2. The first and second heat exchanging portions A1, A2 are correspondingly disposed at the first and second environments E1, E2, respectively. In other words, a part of the case and the first heat exchanging portion A1 are disposed at the first environment E1, and another part of the case and the second heat exchanging portion A2 are disposed at the second environment E2. According to this design, the heat exchanging unit 1 of this disclosure can be manufactured with less amount of components, and the welding processes thereof can be reduced so as to decrease the assembling errors. In addition, as shown in FIG. 2A, the pipe 12 runs through the first heat exchanging portion A1 and then runs through the second heat exchanging portion A2. To be noted, although FIG. 2A shows one pipe 12 only, the heat exchanging unit 1 may comprise a plurality of pipes 12 in other aspects. The distributions of the plurality of pipes 12 are the same as that shown in FIG. 2A, and this disclosure is not limited thereto.

In this embodiment, the circulation loop 3 is communicated to the heat exchanging unit 1 and the compressor 2, and the working fluid flows in the circulation loop 3. The compressor 2 compresses the working fluid for performing the temperature regulation function.

In this embodiment, the first heat exchanging portion A1 is a condensing region, and the second heat exchanging portion A2 is an evaporation region. The first environment E1 can be, for example but not limited to, an outdoor environment or an environment outside the case, and the second environment E2 can be, for example but not limited to, an indoor environment or an environment inside the case. To be noted, the first and second environments E1, E2 are different environments. For example, the communication device, the electronic device and the temperature control apparatus R1 of this disclosure are accommodated in one case, a part of the case and the first heat exchanging portion A1 are disposed at the first environment E1, and another part of the case and the second heat exchanging portion A2 are disposed at the second environment E2. In order to decrease the temperature of the communication device or the electronic device, the second heat exchanging portion A2 in the second environment E2 can absorb the heat, and then the absorbed heat can be carried to the first heat exchanging portion A1 in the first environment E1 for regulating the temperature. In this case, the first heat exchanging portion A1 has a function of a condenser, and the second heat exchanging portion A2 has a function of an evaporator.

In this embodiment, the pipe 12 comprises an inlet 121 and an outlet 122, which are disposed in the first and second heat exchanging portions A1, A2, respectively. The inlet 121 and the outlet 122 of the pipe 12 of the heat exchanging unit 1 are connected with the circulation loop 3. To be noted, although FIG. 2A only shows one pipe 12, the heat exchanging unit 1 may comprise a plurality of pipes 12 in other aspects. The distributions of the plurality of pipes 12 are the same as that shown in FIG. 2A. Each of the plurality of pipes 12 has an inlet 121 and an outlet 122, and the inlets 121 and the outlets 122 of the pipes 12 can be individually connected with the circulation loop 3. Alternatively, the inlets 121 and the outlets 122 of the pipes 12 can be communicated to main pipe together and then connected to the circulation loop 3. This disclosure is not limited thereto.

FIG. 2B is a schematic diagram showing a heat exchanging unit 1a of the temperature control apparatus according to a second embodiment of this disclosure. In this embodiment, the inlet 121a and the outlet 122a of the pipe 12a of the heat exchanging unit 1a are connected with the circulation loop 3. At least one of the pipes 12a has a larger pipe diameter around the inlet 121a and the outlet 122a, and has a smaller pipe diameter away from the inlet 121a and the outlet 122a. Specifically, the pipe 12a has a larger pipe diameter around the inlet 121a and the outlet 122a, and has a smaller pipe diameter away from the inlet 121a and the outlet 122a. The part of the pipe 12a having a smaller pipe diameter is shown in the dotted box A3, and this part has the capillary function for regulating the pressure of the working fluid in the first and second heat exchanging portions A1, A2. This configuration can enhance the heat exchange efficiency of the heat exchanging unit 1a. To be noted, although FIG. 2B shows one pipe 12a only, the heat exchanging unit 1a may comprise a plurality of pipes 12a. At least one of the pipes 12a has a varied pipe diameter from the inlet 121a to the outlet 122a (the pipe diameter is large/small/large in order), so that the heat exchanging unit 1a can have the capillary function. In another aspect, the part of the pipe 12a in the dotted box A3 may have a smaller internal pipe diameter, but the external pipe diameter of the entire pipe 12a is the same. Thus, the outer shape of the pipe 12a has a unique pipe diameter. This configuration can also provide the capillary function for the heat exchanging unit 1a. In some aspects, the pipes 12a have unique internal and external pipe diameters, and the working fluid is not allowed to pass through at least one of the pipes 12a. In other words, at least one of the pipes 12a is blocked, so that the heat exchanging unit 1a can have the capillary function. As shown in FIG. 2B, the part of the heat exchanging unit 1a in the dotted box A3 is a capillary zone, and a total cross-sectional area of the pipes 12a outside the capillary zone is greater than a total cross-sectional area of the pipes in the capillary zone. To be noted, the skilled person in the art can understand the function of the capillary structure and can easily modify it.

Referring to FIG. 1 again, the temperature control apparatus R1 further comprises a first fan 41 and a second fan 42. The first fan 41 is disposed in the first environment E1 corresponding to the first heat exchanging portion A1, and the second fan 42 is disposed in the second environment E2 corresponding to the second heat exchanging portion A2. The first and second fans 41, 42 are configured to induce the airflows for performing heat exchanges in the first and second heat exchanging portions A1, A2, respectively.

Referring to FIGS. 2A and 2B again, in these two embodiments, the heat-dissipating fins 11 can be continuously disposed in the first and second heat exchanging portions A1, A2. In other words, the heat-dissipating fins 11 can be extended to the first and second environments E1, E2. In another embodiment, the heat-dissipating fins 11 are not continuously disposed in the first and second heat exchanging portions A1, A2. This design can be applied to different environments.

In these two embodiments, each of the pipes 12 or pipes 12a can be, for example but not limited to, a flat pipe, a circular pipe, an oval pipe, a rectangular pipe, or a corrugated pipe.

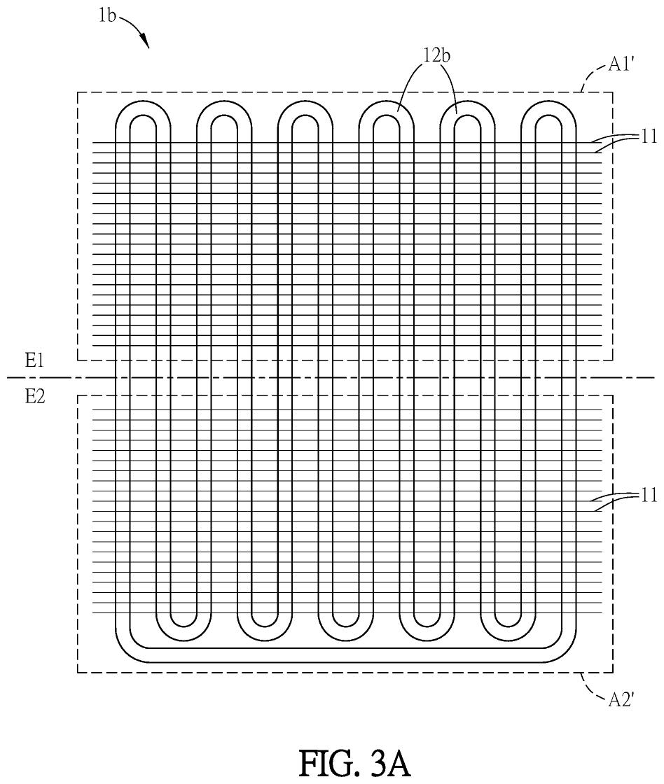

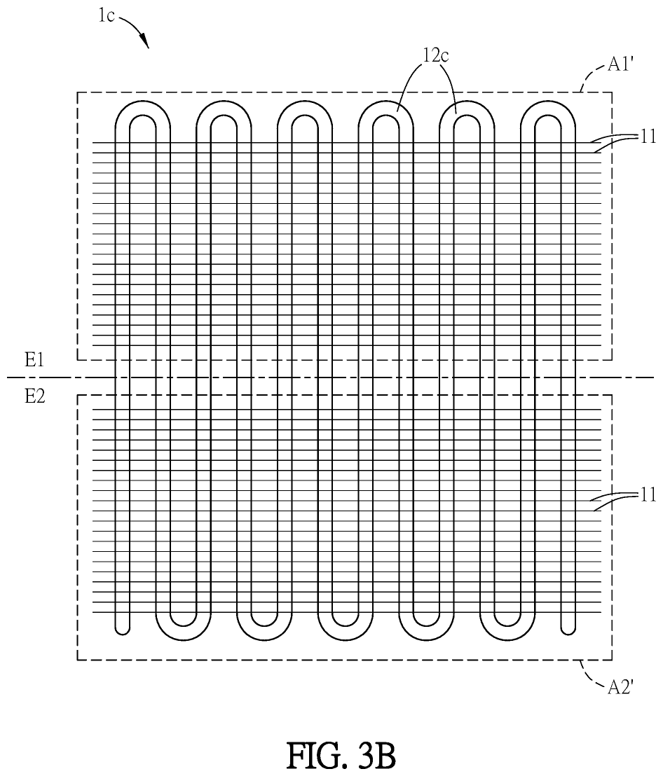

FIG. 3A is a schematic diagram showing a heat exchanging unit 1b according to a third embodiment of this disclosure. In this embodiment, the heat exchanging unit 1b is independently disposed. In other words, the heat exchanging unit 1b is not connected with the compressor 2. As shown in FIG. 3A, the heat exchanging unit 1b is disposed in a first environment E1 and a second environment E2. The heat exchanging unit 1b comprises a plurality of heat-dissipating fins 11, at least one pipe 12b, and at least one working fluid. The heat exchanging unit 1b is divided into a first heat exchanging portion A1′ and a second heat exchanging portion A2′. The pipe 12b runs in the first and second heat exchanging portions A1′, A2′ alternately. The heat-dissipating fins 11 are configured to cool the pipe 12b. The first and second heat exchanging portions A1′, A2′ are correspondingly disposed at the first and second environments E1, E2, respectively. The working fluid is disposed in the pipe 12b for performing the temperature regulation function. Different from the heat exchanging unit 1 of FIG. 2A, the heat exchanging unit 1b has a different arrangement of the pipe 12b. As shown in FIG. 3A, the pipe 12b runs in the first heat exchanging portion A1′ and the second heat exchanging portion A2′ in turn. To be noted, the front part of the pipe 12 of FIG. 2A runs in the first heat exchanging portion A1, and the rear part of the pipe 12 runs in the second heat exchanging portion A2.

In the embodiment as shown in FIG. 3A, the first heat exchanging portion A1′ is a condensing region, and the second heat exchanging portion A2′ is an evaporation region. The first environment E1 can be, for example but not limited to, an outdoor environment or an environment outside the case, and the second environment E2 can be, for example but not limited to, an indoor environment or an environment inside the case. To be noted, the first environment E1 and the second environment E2 are different environments. For example, the communication device, the electronic device and the heat exchanging unit 1b of this disclosure are accommodated in one case, a part of the case and the first heat exchanging portion A1′ are disposed at the first environment E1, and another part of the case and the second heat exchanging portion A2′ are disposed at the second environment E2. In order to decrease the temperature of the communication device or the electronic device, the second heat exchanging portion A2′ in the second environment E2 can absorb the heat, and then the absorbed heat can be carried to the first heat exchanging portion A1′ in the first environment E1 for regulating the temperature. In this case, the first heat exchanging portion A1′ has a function of a condenser, and the second heat exchanging portion A2′ has a function of an evaporator.

In this embodiment, two ends of the pipe 12b are connected to from a closed pipe structure. Specifically, although FIG. 3A only shows one pipe 12b, the heat exchanging unit 1b of this disclosure can comprise a plurality of pipes 12b. The distribution of the pipes 12b can be similar to that shown in FIG. 3A, and two ends of each pipe 12b are connected to form a closed structure. This disclosure is not limited.

In this embodiment, the heat-dissipating fins 11 are not continuously disposed in the first and second heat exchanging portions A1′, A2′. This design can be applied to different environments.

FIG. 3B is a schematic diagram showing a heat exchanging unit 1c according to a fourth embodiment of this disclosure. The features of the heat exchanging unit 1c as shown in FIG. 3B are mostly the same as those of the third embodiment of FIG. 3A. Different from the third embodiment, the two ends of the pipe 12c are not connected to each other and are sealed individually. In this embodiment, the heat exchanging unit 1c is independently disposed. In other words, the heat exchanging unit 1c is not connected with the compressor 2 of the temperature control apparatus R1.

In summary, the temperature control apparatus and the heat exchanging unit of this disclosure can be manufactured with less amount of components, the welding processes thereof can be reduced, and the assembling errors can be decreased. Moreover, the size of the temperature control apparatus can be decreased, the manufacturing cost thereof can be lowered, the entire function thereof can be enhanced, and the heat-dissipation surface can be increased.

Although the present disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present disclosure.

What is claimed is:

1. A temperature control apparatus disposed in a first environment and a second environment, comprising:
a heat exchanging unit independently disposed and divided into a first heat exchanging portion and a second heat exchanging portion, wherein the heat exchanging unit comprises a plurality of heat-dissipating fins and a pipe, two ends of the pipe are connected to from a closed pipe structure, the pipe runs in the first and the second heat exchanging portions alternately, the heat-dissipating fins are not continuously disposed in the first heat exchanging portion and the second heat exchanging portion and configured to cool the pipe, the first heat exchanging portion is correspondingly disposed at the first environment, and the second heat exchanging portion is correspondingly disposed at the second environment; and
a working fluid flowing in the pipe.

2. The temperature control apparatus according to claim 1, wherein the first heat exchanging portion is a condensing region, and the second heat exchanging portion is an evaporation region.

3. The temperature control apparatus according to claim 1, wherein the first environment and the second environment are different environments.

4. The temperature control apparatus according to claim 3, wherein the first environment is an outdoor environment and the second environment is an indoor environment.

5. The temperature control apparatus according to claim 1, wherein the pipe is a flat pipe.

6. The temperature control apparatus according to claim 1, further comprising a first fan and a second fan, wherein the first fan is disposed in the first environment corresponding to the first heat exchanging portion, and the second fan is disposed in the second environment corresponding to the second heat exchanging portion.
